(19) United States
(12) Patent Application Publication
(10) Pub. No.: US 2004/0014275 A1
(43) Pub. Date: Jan. 22, 2004

(54) Method of manufacturing a semiconductor device

(76) Inventors: Hisashi Hasegawa, Chiba-shi (JP); Jun Osani, Chiba-shi (JP)

Correspondence Address: Adams & Wilks, 50 Broadway, 31st Floor, New York, NY, 10004, US

(21) Appl. No.: 10/398,034

(22) PCT Filed: Jun. 18, 2002
(86) PCT No.: PCT/JP02/06073

(30) Foreign Application Priority Data
Jun. 19, 2001 (JP) 2001-184698

(51) Int. Cl. H01L 21/8238; H01L 21/336

(52) U.S. Cl. 438/227; 438/231; 438/305

(57) ABSTRACT

There is provided a manufacturing method for a structure capable of realizing a power management semiconductor device and an analog semiconductor device in which a cost is low, a work period is short, and low voltage operation is possible, which have low power consumption and high drive capacity, and which is high function and high precision. The manufacturing method is a method of obtaining a P-type polycide structure as a laminate structure of a P-type polycrystalline silicon film and a high melting point metallic silicide film for respective gate electrodes of an NMOS transistor and a PMOS transistor as divided by a conductivity type thereof in a CMOS transistor. In addition, a resistor used for a voltage dividing circuit and a CR circuit is formed by using a polycrystalline silicon film as a layer different from the gate electrode, so that higher precision resistor can be provided.

### TECHNICAL FIELD

The present invention relates to a method of manufacturing a complementary MOS semiconductor device having a resistor circuit, for which low voltage operation, low power consumption, and high drive power are required. In particular, the present invention relates to a power management semiconductor device such as a voltage detector (hereinafter referred to as a VD), a voltage regulator (hereinafter referred to as a VR), or a switching regulator (hereinafter referred to as an SWR), or an analog semiconductor device such as an operational amplifier or a comparator.

### BACKGROUND ART

Conventionally, many kinds of complementary MOS semiconductor devices having a resistor circuit using a resistor made of polycrystalline silicon or the like are used. FIG. 14 shows an example of a structure of a conventional semiconductor device having a resistor circuit. There is formed a complementary MOS (hereinafter referred to as a CMOS) structure which is comprised of an N-channel MOS (hereinafter referred to as an NMOS) transistor 214 in which a gate electrode 221 formed on a gate insulating film 205 of a P-type semiconductor substrate 201 is made of N⁺-type polycrystalline silicon, and a P-channel MOS (hereinafter referred to as a PMOS) transistor 215 in which the gate electrode 221 formed to an N-well region 202 is also made of N⁺-type polycrystalline silicon. There are formed impurity diffusion layers 203 and 204 as components of MOS transistors 214 and 215. There are formed resistors 216 and 217 used for a voltage dividing circuit for dividing a voltage, a CR circuit for setting a time constant, or the like, which are formed on a field insulating film 206. These components constitute a resistor circuit. Here, the resisters 216 and 217 are respectively composed of high concentration impurity regions 208 and 209 and high resistance regions 210 and 211.

In the complementary MOS (CMOS) semiconductor device having the resistor circuit, the N⁺-type polycrystalline silicon is often used for the gate electrode in view of a polarity thereof because of ease and stability of the manufacturing operation. In this case, from a relationship of work functions between the gate electrode and the semiconductor substrate (well), the NMOS transistor becomes a surface channel type NMOS transistor. On the other hand, in the case of the PMOS transistor, a threshold voltage becomes about −1 V also from the relationship of work functions between the gate electrode and the semiconductor substrate. Thus, when impurity implantation is conducted for reducing the threshold voltage, the PMOS transistor becomes a buried channel type PMOS transistor in which a channel is formed in the inner portion of the substrate, which is slightly deeper than the surface thereof. The buried channel type transistor has an advantage of high mobility because a carrier is transferred through the inner portion of the substrate. However, when the threshold voltage is reduced, a subthreshold characteristic is greatly deteriorated, thereby increasing a leak current. Thus, it is difficult for the PMOS transistor to reduce a voltage and shorten a channel as compared with the NMOS transistor.

Also, as a structure capable of reducing a voltage in both the NMOS transistor and the PMOS transistor, there is a homopolar gate structure in which the polarity of the gate electrode is set to be equal to that of the transistor. According to this structure, N⁺-type polycrystalline silicon is used for the gate electrode of the NMOS transistor and P⁺-type polycrystalline silicon is used for the gate electrode of the PMOS transistor. Thus, each transistor becomes a surface channel type transistor. As a result, a leak current can be suppressed and a voltage can be reduced. However, there are the following problems in costs and characteristics. That is, when the gate electrodes having different polarities are formed, the number of manufacturing steps is thereby increased and increases in a manufacturing cost and a manufacturing period are caused. Further, with respect to an inverter circuit as a most fundamental circuit element, generally, in order to improve area efficiency, the layout for the gate electrodes of the NMOS transistor and the PMOS transistor is made such that a connection through metal is avoided and a piece of polycrystalline silicon which is two-dimensionally continued from the NMOS transistor to the PMOS transistor or a polycide structure composed of a laminate of a polycrystalline silicon film and a high melting point metallic silicide film is used. However, when the gate electrode is made of polycrystalline silicon as a single layer, it is impractical because of a high impedance of a PN junction in the polycrystalline silicon. Also, when the gate electrode has a polycide structure, an N-type impurity and a P-type impurity each are diffused to respective gate electrodes having an inverse conductivity type through high melting point metallic silicide films at high speed during heat treatment in manufacturing steps. As a result, a work function is changed and a threshold voltage is unstable.

### DISCLOSURE OF THE INVENTION

In order to solve the above-mentioned problems, the present invention adopts the following measures.

(1) A method of manufacturing a semiconductor device including the steps of: forming an element isolation insulating film on a semiconductor substrate by thermal oxidation; forming a gate insulating film by thermal oxidation; depositing a first polycrystalline silicon film having 500 Å to 2500 Å on the gate insulating film; doping the first polycrystalline silicon film with an impurity such that a concentration of the impurity is 1×10¹⁸ atoms/cm³ or higher to make a conductivity type of the first polycrystalline silicon film a P-type; depositing a high melting point metallic silicide film having 500 Å to 2500 Å on the first polycrystalline silicon film having the P-type; depositing an insulating film having a thickness of 500 Å to 3000 Å on the high melting point metallic silicide film; etching the first polycrystalline silicon film having the P-type, the high melting point metallic silicide film, and the insulating film to form a laminate polycide gate electrode; doping a low concentration diffusion region of a first conductivity type MOS transistor with a first conductivity type impurity at a concentration of 1×10¹⁶ to 1×10¹⁸ atoms/cm³; doping a low concentration diffusion region of a second conductivity type MOS transistor with a second conductivity type impurity at a concentration of 1×10¹⁶ to 1×10¹⁸ atoms/cm³; depositing an insulating film having a film thickness of the same order as the polycide gate electrode on the polycide gate electrode; etching the insulating film by anisotropic dry etching to form a side spacer on a side wall of the polycide gate electrode; depositing a second polycrystalline silicon film having a thickness of 500 Å to 2500 Å on the element isolation insulating film; doping an entire region of the second polycrystalline silicon film or a first region of the second polycrystalline silicon film with the second conductivity type impurity at a concentration of 1×10¹⁴ to 9×10¹⁸ atoms/cm³; doping a second region of the second polycrystalline silicon film with the first conductivity type impurity at a concentration of 1×10¹⁴ to 9×10¹⁸ atoms/cm³; etching the second polycrystalline silicon film to form a resistor of the second polycrystalline silicon film; doping a portion or the entire region of the first region of the second polycrystalline silicon film with the first conductivity type impurity at a concentration of 1×10¹⁹ atoms/cm³ or higher; doping a portion or the entire region of the second region of the second polycrystalline silicon film with the second conductivity type impurity at a concentration of 1×10¹⁹ atoms/cm³ or higher; forming an intermediate insulating film over the semiconductor substrate; forming a contact hole in the intermediate insulating film over the semiconductor substrate; and providing a metallic wiring in the contact hole.

(2) A method of manufacturing a semiconductor device, characterized in that an impurity introducing method for the first polycrystalline silicon film is for ion implantation of boron.

(3) A method of manufacturing a semiconductor device, characterized in that an impurity introducing method for the first polycrystalline silicon film is for ion implantation of BF₂.

(4) A method of manufacturing a semiconductor device, characterized in that an impurity introducing method for the first polycrystalline silicon film is a doped-CVD method of depositing the first polycrystalline silicon film while the impurity is mixed thereinto.

(5) A method of manufacturing a semiconductor device, characterized in that the insulating film deposited on the high melting point metallic silicide film is composed of an oxide film.

(6) A method of manufacturing a semiconductor device, characterized in that, when the insulating film deposited on the high melting point metallic silicide film is an oxide film, the insulating film which becomes a material of a side spacer formed on the side wall of the polycide gate electrode is a nitride film.

(7) A method of manufacturing a semiconductor device, characterized in that the insulating film deposited on the high melting point metallic silicide film is composed of a nitride film.

(8) A method of manufacturing a semiconductor device, characterized in that, when the insulating film deposited on the high melting point metallic silicide film is a nitride film, the insulating film which becomes a material of a side spacer formed on the side wall of the polycide gate electrode is an oxide film.

(9) A method of manufacturing a semiconductor device, characterized in that the insulating film deposited on the high melting point metallic silicide film is composed of a laminate structure of an oxide film, a nitride film, and another oxide film different from the oxide film.

(10) A method of manufacturing a semiconductor device, characterized in that, when the insulating film deposited on the high melting point metallic silicide film has a laminate structure and an uppermost layer thereof is an oxide film, the insulating film which becomes a material of a side spacer formed on the side wall of the polycide gate electrode is a nitride film.

(11) A method of manufacturing a semiconductor device, characterized in that doping of the first conductivity type impurity at a concentration of 1×10¹⁹ atoms/cm³ or higher to the portion and the entire region of the first region of the second polycrystalline silicon film is performed simultaneously with doping to a diffusion region of the first conductivity type MOS transistor, and doping of the second conductivity type impurity at a concentration of 1×10¹⁹ atoms/cm³ or higher to the portion and the entire region of the second region of the second polycrystalline silicon film is performed simultaneously with doping to a diffusion region of the second conductivity type MOS transistor.

### BRIEF DESCRIPTION OF THE DRAWINGS

FIG. 1 is a schematic cross sectional view showing a CMOS semiconductor device according to an embodiment of the present invention.

FIG. 2 is a cross sectional view showing a method of manufacturing the CMOS semiconductor device in step order according to the present invention.

FIG. 3 is a cross sectional view showing a method of manufacturing the CMOS semiconductor device in step order according to the present invention.

FIG. 4 is a cross sectional view showing a method of manufacturing the CMOS semiconductor device in step order according to the present invention.

FIG. 5 is a cross sectional view showing a method of manufacturing the CMOS semiconductor device in step order according to the present invention.

FIG. 6 is a cross sectional view showing a method of manufacturing the CMOS semiconductor device in step order according to the present invention.

FIG. 7 is a cross sectional view showing a method of manufacturing the CMOS semiconductor device in step order according to the present invention.

FIG. 8 is a cross sectional view showing a method of manufacturing the CMOS semiconductor device in step order according to the present invention.

FIG. 9 is a cross sectional view showing a method of manufacturing the CMOS semiconductor device in step order according to the present invention.

FIG. 10 is a cross sectional view showing a method of manufacturing the CMOS semiconductor device in step order according to the present invention.

FIG. 11 is a cross sectional view showing a method of manufacturing the CMOS semiconductor device in step order according to the present invention.

FIG. 12 is a cross sectional view showing a method of manufacturing the CMOS semiconductor device in step order according to the present invention.

FIG. 13 is a cross sectional view showing a method of manufacturing the CMOS semiconductor device in step order according to the present invention.

FIG. 14 is a schematic cross sectional view showing an embodiment of a conventional CMOS semiconductor device.

### BEST MODE FOR CARRYING OUT THE INVENTION

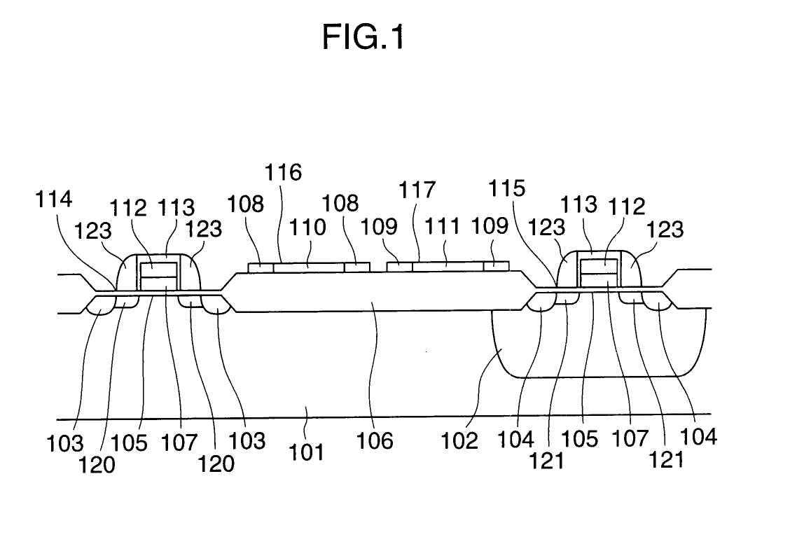

Hereinafter, an embodiment of the present invention will be described in detail using the drawings. FIG. 1 is a cross sectional view showing a CMOS semiconductor device having a resistor circuit according to an embodiment of the present invention.

In this embodiment, an N-type well diffusion layer region 102 is formed in a P-type silicon semiconductor substrate 101 and has a conductivity type opposite to the substrate. Further, impurity diffusion layers each having a conductivity type opposite to the silicon semiconductor substrate 101 are formed therein for an N-type MOS transistor 114. Impurity diffusion layers each having a conductivity type opposite to the N-type well diffusion layer region 102 are formed therein for a P-type MOS transistor 115. Each of the transistors is composed of a gate insulating film 105 and a gate electrode in addition to the impurity diffusion layer. The gate electrode has a laminate polycide structure of a P⁺-type polycrystalline silicon film 107 and a high melting point metallic silicide film 112. An oxide insulating film 113 is deposited on the gate electrode as a mask member therefor. Here, a nitride film may be used as the mask member for the gate electrode. In addition, the P-type silicon semiconductor substrate is used here. However, a P-type well diffusion layer may be formed in an N-type silicon substrate so as to construct a CMOS semiconductor device thereto.

Also, in this embodiment, a polycrystalline silicon resistor 116 which is made from a second polycrystalline silicon film and has an N-type as a first conductivity type and a polycrystalline silicon resistor 117 which is made from the second polycrystalline silicon film and has a P-type as a second conductivity type are formed on a field insulating film 106. Here, the polycrystalline silicon film 107 as a portion of the gate electrode in the CMOS transistor and the polycrystalline silicon resistors 116 and 117 are formed in separate steps and have different film thicknesses. The polycrystalline silicon resistors are formed to be thinner than the gate electrode. For example, the film thickness of the gate electrode is about 2000 Å to 6000 Å. On the other hand, the film thickness of each resistor is 500 Å to 2500 Å. When the polycrystalline silicon resistors are thin, a high sheet resistance value can be set and a temperature characteristic becomes preferable. Thus, the accuracy of resistor can be further improved.

The N-type polycrystalline silicon resistor 116 includes a high resistance region 110 and high concentration impurity regions 108 which are provided in both end portions of the resistor such that they are in sufficient contact with wiring members. The impurity concentration of the high resistance region 110 is controlled by ion implantation, thereby forming the resistors each having a desirable resistance value. Similarly, the P-type polycrystalline silicon resistor 117 includes a high resistance region 111 and high concentration impurity regions 109. A resistance value is set in accordance with the impurity concentration of the high resistance region.

For example, a sheet resistance value is dependent on a use of the resistor. In the case of a general voltage dividing circuit, the sheet resistance value from several kΩ/square to several tens kΩ/square is used. At this time, boron or BF₂ is used as an impurity for the P⁻-type resistor 117 and the concentration thereof is about 1×10¹⁴ to 9×10¹⁸ atoms/cm³. Phosphorus or arsenic is used as an impurity for the N-type resistor 116 and the concentration thereof is about 1×10¹⁴ to 9×10¹⁸ atoms/cm³.

Also, both the N-type resistor 116 and the P-type resistor 117 are shown in FIG. 1. However, in order to reduce the number of steps and costs in view of features of those resistors and characteristics thereof required for a product, there is the case where only one of the N-type resistor 116 and the P-type resistor 117 is mounted.

Thus, when the gate electrode is set to be the P⁺-type, the PMOS transistor becomes the surface channel type PMOS transistor. Therefore, even when the threshold voltage is reduced, a leak current can be suppressed as compared with the buried channel type transistor. On the other hand, in the case of the NMOS transistor, when the gate electrode is set to be the P⁺-type, it becomes the buried channel type NMOS transistor. Here, arsenic having a smaller diffusion coefficient than boron is used as an impurity to be implanted for reducing the threshold voltage. Thus, the NMOS transistor becomes a state similar to the surface channel type transistor as compared with the PMOS transistor using an N⁺-type gate electrode. In addition, arsenic has the property of condensing near an interface between the silicon film and the oxide film. Therefore, the NMOS transistor further approaches a state similar to the surface channel type transistor. As a result, even when the threshold voltage is reduced in the N-type MOS transistor, a leak current can be suppressed and low voltage operation is possible. With respect to the homopolar gate structure, when the respective gate electrodes of the N-type MOS transistor and the P-type MOS transistor are set to be the P⁺-type, manufacturing steps are thereby simplified and costs can be reduced.

Further, in FIG. 1, for the purpose of improvement of channel length modulation, suppression of reduction in reliability resulting from a hot carrier, and improvement of a drain withstand voltage, which are important for an analog circuit, a MOS transistor structure is used which is a so-called lightly doped drain (LDD) structure which has, in the source and the drain, low concentration impurity diffusion layers N 120 and P 121, and high concentration impurity diffusion layers N+ 103 and P+ 104 provided apart from the gate electrode by a distance corresponding to a side spacer 123. This structure is an advantageous structure with respect to miniaturization because the high concentration impurity diffusion layers are formed in self alignment, but contrarily has a demerit that there is a limitation on the improvement of the withstand voltage.

The LDD structure shown in FIG. 1 is formed as follows. For example, low concentration impurity diffusion layers are formed by an ion implantation method and heat treatment, an insulating film is then deposited by a CVD method (chemical vapor deposition method), anisotropic dry etching is conducted to form side spacers, and high concentration impurity diffusion layers are provided in self alignment by the ion implantation method. With respect to the low concentration impurity diffusion layers, in the case of N 120 of the NMOS transistor 114, phosphorus or arsenic is used as an impurity and a concentration is about 1×10¹⁶ to 1×10¹⁸ atoms/cm³. In the case of P 121 of the PMOS transistor 115, boron or BF₂ is used as an impurity and the concentration is about 1×10¹⁶ to 1×10¹⁸ atoms/cm³. With respect to the high concentration impurity diffusion layers, in the case of N+ 103 of the NMOS transistor 114, phosphorus or arsenic is used as an impurity and a concentration is 1×10¹⁹ atoms/cm³ or higher. In the case of P+ 104 of the PMOS transistor 115, boron or BF₂ is used as an impurity and the concentration is 1×10¹⁹ atoms/cm³ or higher. In addition, a width of the side spacers 123 is generally about 0.2 μm to 0.5 μm.

From the above-mentioned description, a method of manufacturing the CMOS transistor using a P⁺-type polycrystalline silicon unipole as the gate electrode according to the present invention is a technique effective in low voltage operation and low power consumption as compared with a method of manufacturing a conventional CMOS transistor using an N⁺-type polycrystalline silicon unipole as the gate electrode. Further, the semiconductor device includes the polycrystalline silicon resistor different from the gate electrode and the LDD structure transistor, thereby further enabling high grade function and high accuracy which are necessary for the analog circuit.

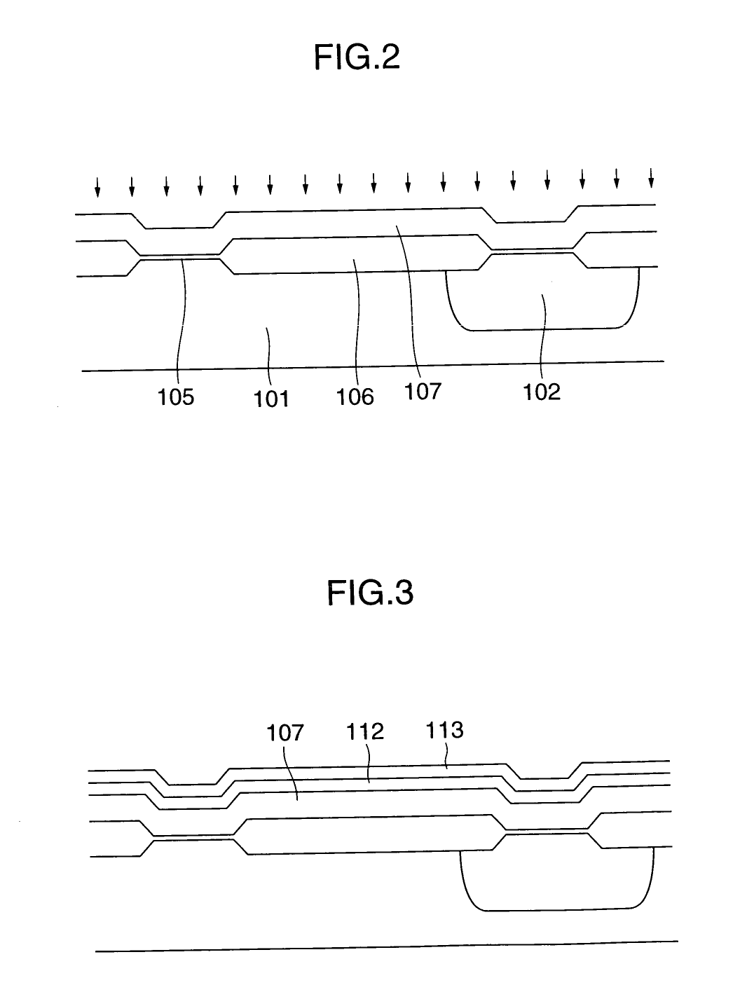

Next, steps of manufacturing the semiconductor device of the embodiment shown in FIG. 1 will be described based on FIG. 2.

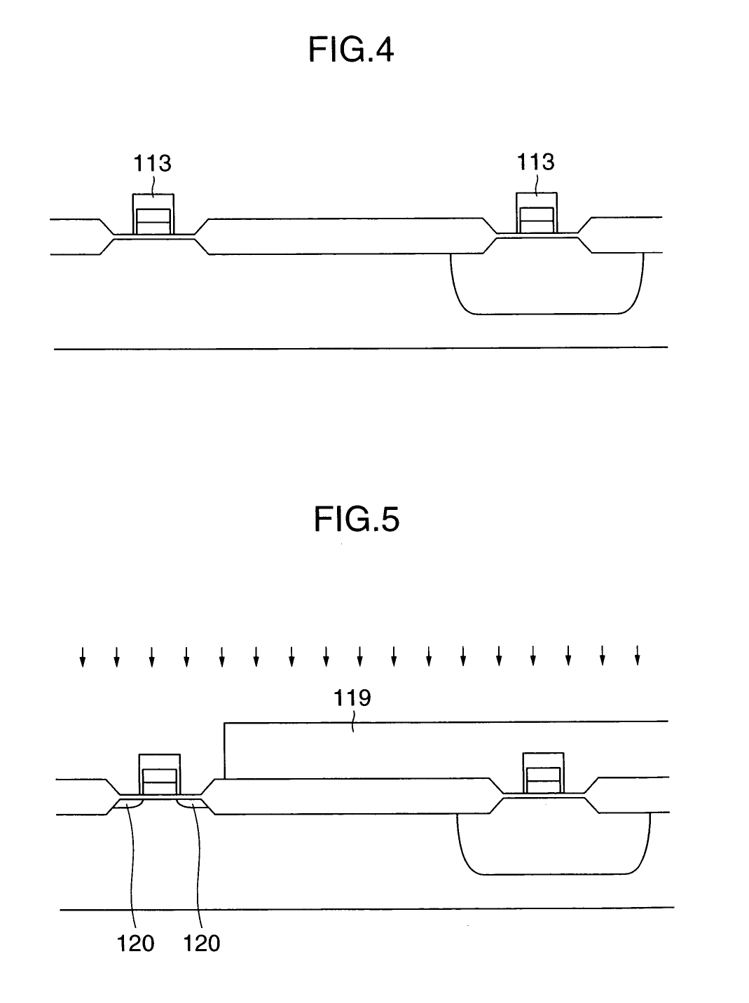

For example, phosphorus ions are implanted into the P-type silicon semiconductor substrate 101 and annealing is performed at 1000° C. to 1175° C. for 3 hours to 20 hours. Thus, the phosphorus ions are diffused to form the N-type well diffusion layer 102 having an impurity concentration of about 1×10¹⁶ atoms/cm³. Subsequently, the field insulating film 106 is formed by a LOCOS method, the gate insulating film 105 is formed at a film thickness of about 100 Å to 300 Å by thermal oxidation, and ion implantation is performed for obtaining a predetermined threshold voltage. After that, a first polycrystalline silicon film is deposited at a film thickness of about 500 Å to 2500 Å by a low pressure CVD method. Then, boron ions or BF₂ ions are implanted into this first polycrystalline silicon film such that the impurity concentration thereof is equal to or higher than 1×10¹⁸ atoms/cm³, thereby forming the P⁺-type polycrystalline silicon film 107 (FIG. 2). Here, the P⁺-type polycrystalline silicon film is formed by ion implantation. However, the P⁺-type polycrystalline silicon film may be formed by a doped-CVD method of depositing a polycrystalline silicon film while an impurity such as boron is mixed thereinto at the same time. After that, a tungsten silicide film 112 as the high melting point metallic silicide film is deposited on the P⁺-type polycrystalline silicon film by a sputtering method or the like. Note that, here, the tungsten silicide film is used as the high melting point metallic silicide film. However, a molybdenum silicide film, a titanium silicide film, or a platinum silicide film can be also used. Then, the oxide insulating film 113 as a mask member for preventing introduction of an N-type impurity into a P⁺-type gate electrode is deposited on the high melting point metallic silicide film 112 at 500 Å to 3000 Å by the low pressure CVD method (FIG. 3) and patterned using a photo resist to form the P⁺-type gate electrode. Here, a nitride film may be used as the mask member. Then, an oxide film is formed at 100 Å to 500 Å to a gate electrode portion and on the surface of the semiconductor substrate by thermal oxidation, the low pressure CVD method, or the like (FIG. 4). In addition, here, as the insulating film 113 on the P⁺-type gate electrode, an insulating film having a laminate structure of an oxide film having a film thickness of, for example, 300 Å, a nitride film having a film thickness of 500 Å, which is formed by the CVD method, and a thermal oxide film having a film thickness of about 10 Å may be formed for forming a high quality capacitor.

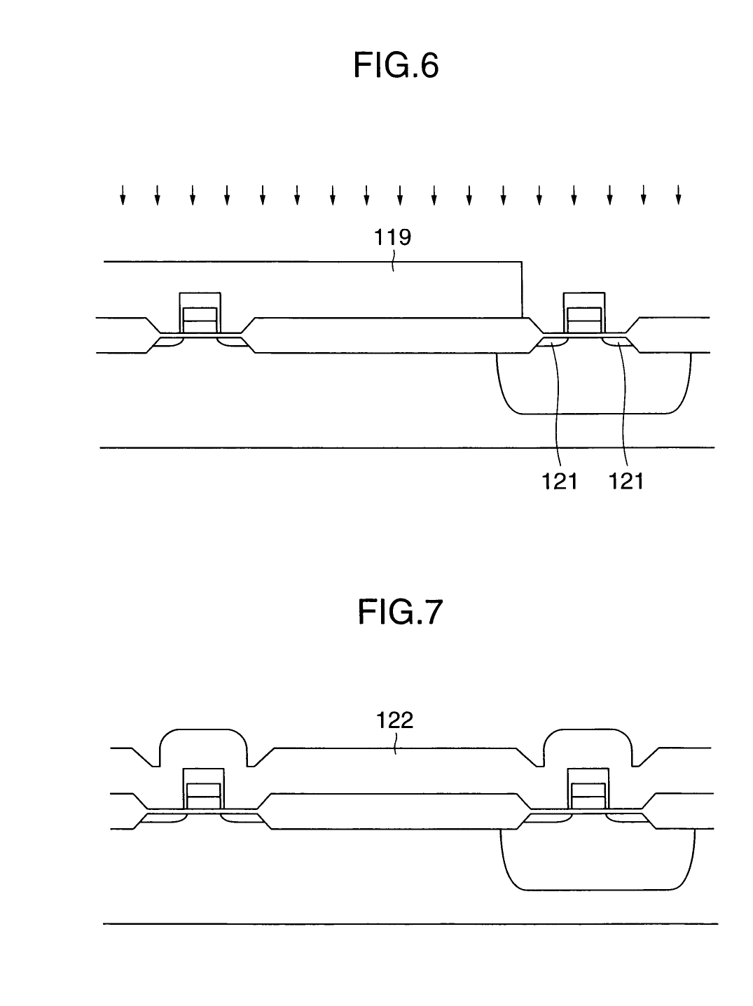

Next, as shown in FIG. 5, the photo resist 119 is patterned, arsenic or phosphorus as an N-type impurity is doped by the ion implantation method such that the impurity concentration becomes about 1×10¹⁶ to 1×10¹⁸ atoms/cm³, thereby forming N-type low concentration impurity regions 120 as the source and the drain of the NMOS transistor. Then, after the removal of the photo resist, as shown in FIG. 6, a new photo resist 119 is patterned, boron or BF₂ as a P-type impurity is doped by the ion implantation method such that an impurity concentration becomes about 1×10¹⁶ to 1×10¹⁸ atoms/cm³, thereby forming a P-type low concentration impurity region 121 as the drain of the PMOS transistor.

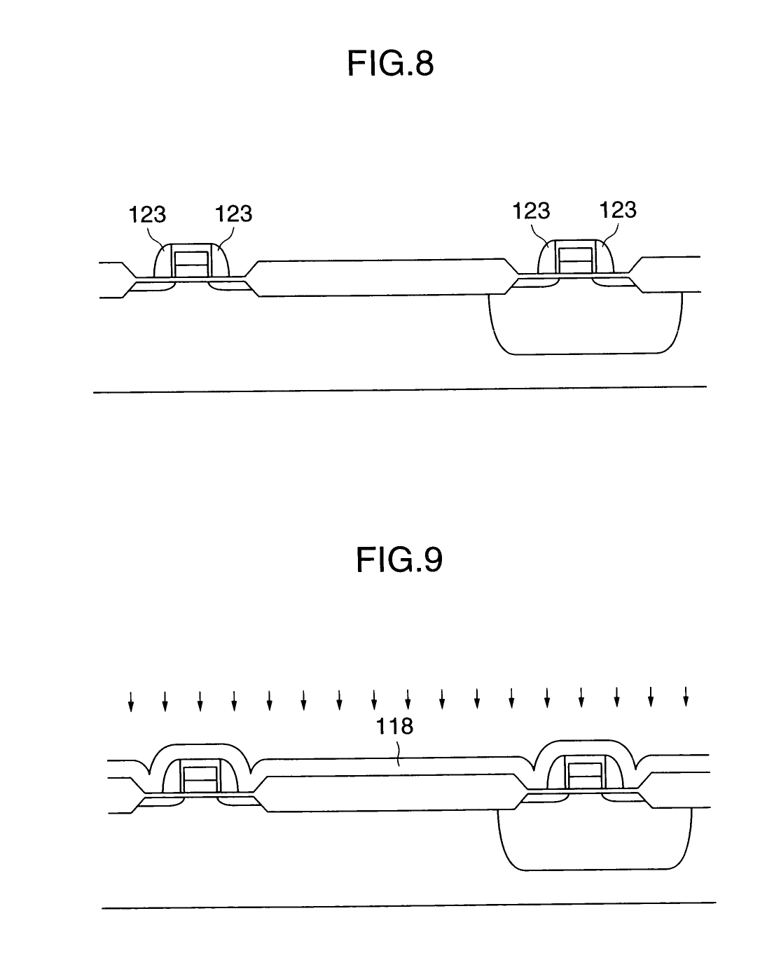

Next, as shown in FIG. 7, an insulating film 122 is deposited by the CVD method (chemical vapor deposition method) in order to form side spacers on gate electrode side walls. At this time, when an oxide film is used for the insulating film as a mask member of the gate electrode, a nitride film is deposited as a spacer member. When a nitride film is used as the mask member, an oxide film is deposited as the spacer member. This is because an etching selection ratio between the mask member of the gate and the spacer member is obtained in spacer etching. After that, RIE anisotropic dry etching is conducted to form side spacers 123 as shown in FIG. 8.

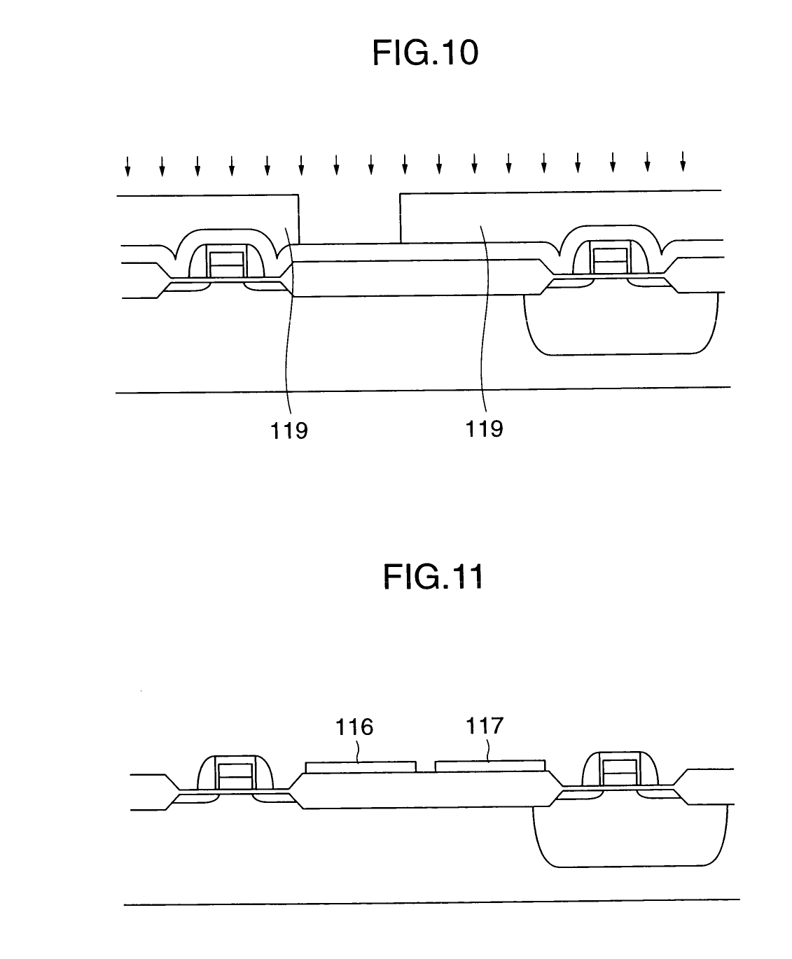

After that, as shown in FIG. 9, a second polycrystalline silicon film 118 having a film thickness of, for example, 1000 Å is deposited by the CVD method or the sputtering method. Then, in order to form a low concentration P-type resistor, ion implantation of BF₂ as a P-type impurity is conducted to the entire surface of the second polycrystalline silicon film 118 at a dose of, for example, 1×10¹⁴ atoms/cm². Note that boron may be used instead of BF₂. After that, as shown in FIG. 10, a low concentration N-type resistor region is patterned using the photo resist 119 and selective ion implantation of phosphorus is conducted at a dose of, for example, 3×10¹⁴ atoms/cm². At this time, in order to stably form an N-type resistor, it is required that the dose of phosphorus is set to be equal to or more than two times the dose of BF₂. Note that arsenic may be used instead of phosphorus. Thus, when boron for setting a sheet resistance value of the P-type resistor is introduced in advance into a polycrystalline silicon resistor region which becomes the N-type later and it is reinjected to the N-type resistor region later using phosphorus or arsenic as an N-type impurity, the sheet resistance value can be effectively increased. Note that a method of separately performing ion implantation to the P-type resistor region and the N-type resistor region using respective masks made of a photo resist or the like may be used.

After that, the photo resist 119 is removed, and then patterning is performed using a photo resist and RIE anisotropic dry etching is performed, thereby forming the polycrystalline silicon resistor 116 having the N-type as the first conductivity type and the polycrystalline silicon resistor 117 having the P-type as the second conductivity type, as shown in FIG. 11.

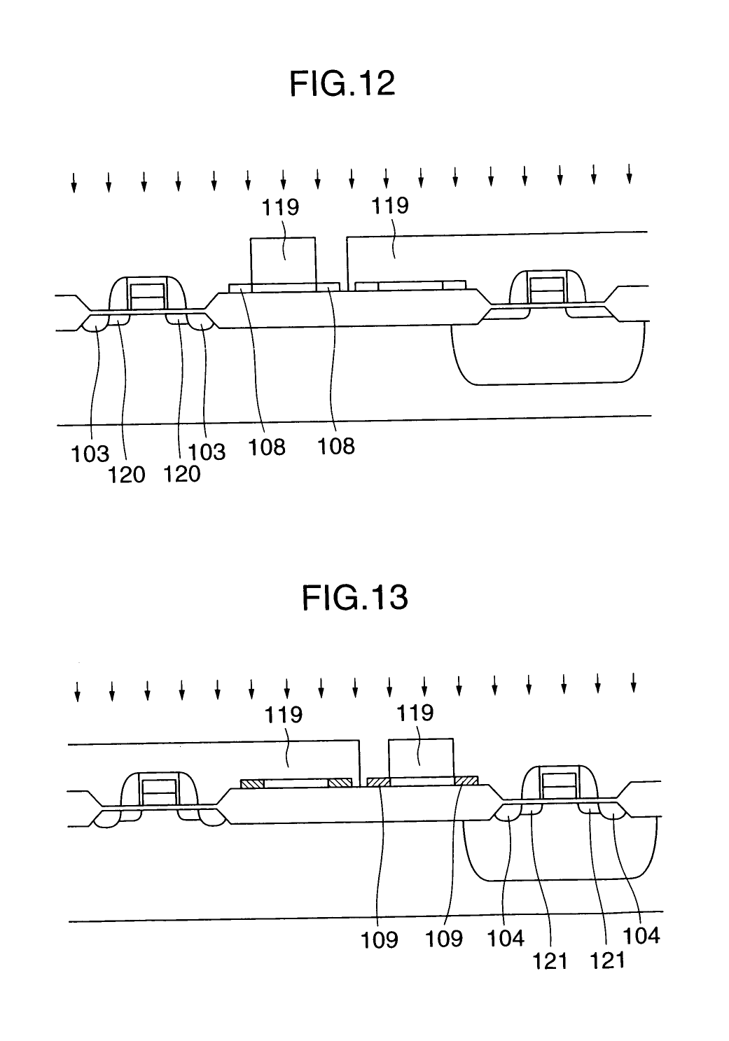

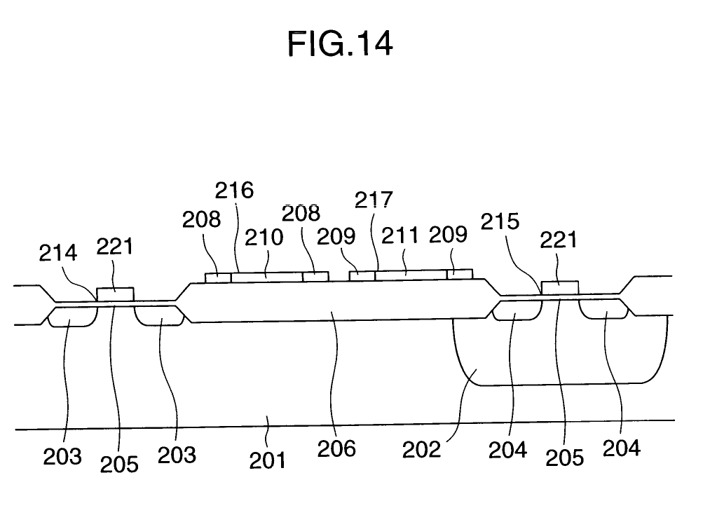

Next, as shown in FIG. 12, patterning is performed using the photo resist 119 and arsenic as the N-type impurity is doped at a dose of 5×10¹⁵ atoms/cm² by the ion implantation method. As a result, the high concentration impurity regions 108 for sufficiently contacting an aluminum wiring in the second polycrystalline silicon resistor 116 having the N-type as the first conductivity type and N-type high concentration impurity regions 103 to be the source and the drain of the NMOS transistor are simultaneously formed. Instead of the introduction of the N-type impurity into the second polycrystalline silicon resistor as shown in FIG. 10 which is omitted, the N-type high concentration impurity in FIG. 12 can be doped into the entire region of the N-type resistor to form the N-type resistor having a relatively low resistance.

Then, after the photo resist is removed, as shown in FIG. 13, patterning is performed using a photo resist 119 and BF₂ as the P-type impurity is doped at a dose of 5×10¹⁵ atoms/cm² by the ion implantation method. As a result, the high concentration impurity regions 109 for sufficiently contacting the aluminum wiring in the second polycrystalline silicon resistor 117 having the P-type as the second conductivity type and P-type high concentration impurity regions 104 to be the source and the drain of the PMOS transistor are simultaneously formed. In FIG. 13, the P-type high concentration impurity can be doped into the entire region of the P-type resistor to form the P-type resistor having a relatively low resistance.

After that, although not shown, as in a conventional semiconductor process, formation of an intermediate insulating film, formation of contact holes, formation of an aluminum wiring pattern, and formation of a protective film and patterning thereof are performed to produce the complementary MOS semiconductor device.

Thus, the embodiment mode of the present invention is described based on the embodiment using the P-type semiconductor substrate. Even when the polarity of the substrate is reversed and the P⁺-type unipolar gate CMOS transistor of N-substrate P-well type is produced using the N-type semiconductor substrate, a semiconductor device achieving low voltage operation, low power consumption, and a low cost can be provided as in contents and principles as described above.

Industrial Applicability

As described above, with respect to a power management semiconductor device and an analog semiconductor device which each include a CMOS transistor and a resistor, a manufacturing method of the present invention is a method of obtaining a P-type polycide structure as a laminate structure of a P-type polycrystalline silicon film and a high melting point metallic silicide film for the respective gate electrodes of both the NMOS transistor and the PMOS transistor as divided by the conductivity type thereof in the CMOS transistor, and further a semiconductor device manufacturing method in which a resistor used for a voltage dividing circuit and a CR circuit is formed by using a polycrystalline silicon film as a layer different from the gate electrode so that a higher accurate resistor can be obtained. Consequently, as compared with a conventional CMOS transistor having an N⁺-type polycrystalline silicon gate unipole and a conventional homopolar gate CMOS transistor in which the channel and the gate electrode have the same polarity, there is advantages in costs, manufacturing periods, and element performances. In addition, a power management semiconductor device and an analog semiconductor device which have high grade function and high accuracy can be realized.

1. A method of manufacturing a semiconductor device comprising the steps of: forming an element isolation insulating film on a semiconductor substrate by thermal oxidation; forming a gate insulating film by thermal oxidation; depositing a first polycrystalline silicon film having 500 Å to 2500 Å on the gate insulating film; doping the first polycrystalline silicon film with an impurity such that a concentration of the impurity is 1×10¹⁸ atoms/cm³ or higher to make a conductivity type of the first polycrystalline silicon film a P-type; depositing a high melting point metallic silicide film having 500 Å to 2500 Å on the first polycrystalline silicon film having the P-type; depositing an insulating film having a thickness of 500 Å to 3000 Å on the high melting point metallic silicide film; etching the first polycrystalline silicon film having the P-type, the high melting point metallic silicide film, and the insulating film to form a laminate polycide gate electrode; doping a low concentration diffusion region of a first conductivity type MOS transistor with a first conductivity type impurity at a concentration of 1×10¹⁶ to 1×10¹⁸ atoms/cm³; doping a low concentration diffusion region of a second conductivity type MOS transistor with a second conductivity type impurity at a concentration of 1×10¹⁶ to 1×10¹⁸ atoms/cm³; depositing an insulating film having a film thickness of the same order as the polycide gate electrode on the polycide gate electrode; etching the insulating film by anisotropic dry etching to form a side spacer on a side wall of the polycide gate electrode; depositing a second polycrystalline silicon film having a thickness of 500 Å to 2500 Å on the element isolation insulating film; doping an entire region of the second polycrystalline silicon film or a first region of the second polycrystalline silicon film with the second conductivity type impurity at a concentration of 1×10¹⁴ to 9×10¹⁸ atoms/cm³; doping a second region of the second polycrystalline silicon film with the first conductivity type impurity at a concentration of 1×10¹⁴ to 9×10¹⁸ atoms/cm³; etching the second polycrystalline silicon film to form a resistor of the second polycrystalline silicon film; doping a portion or the entire region of the first region of the second polycrystalline silicon film with the first conductivity type impurity at a concentration of 1×10¹⁹ atoms/cm³ or higher; doping a portion or the entire region of the second region of the second polycrystalline silicon film with the second conductivity type impurity at a concentration of 1×10¹⁹ atoms/cm³ or higher; forming an intermediate insulating film over the semiconductor substrate; forming a contact hole in the intermediate insulating film over the semiconductor substrate; and providing a metallic wiring in the contact hole.

2. A method of manufacturing a semiconductor device as set forth in claim 1, characterized in that an impurity introducing method for the first polycrystalline silicon film is for ion implantation of boron.

3. A method of manufacturing a semiconductor device as set forth in claim 1, characterized in that an impurity introducing method for the first polycrystalline silicon film is for ion implantation of BF₂.

4. A method of manufacturing a semiconductor device as set forth in claim 1, characterized in that an impurity introducing method for the first polycrystalline silicon film is a doped-CVD method of depositing the first polycrystalline silicon film while the impurity is mixed thereinto.

5. A method of manufacturing a semiconductor device as set forth in claim 1, characterized in that the insulating film deposited on the high melting point metallic silicide film is composed of an oxide film.

6. A method of manufacturing a semiconductor device as set forth in claim 5, characterized in that, when the insulating film deposited on the high melting point metallic silicide film is an oxide film, the insulating film which becomes a material of a side spacer formed on the side wall of the polycide gate electrode is a nitride film.

7. A method of manufacturing a semiconductor device as set forth in claim 1, characterized in that the insulating film deposited on the high melting point metallic silicide film is composed of a nitride film.

8. A method of manufacturing a semiconductor device as set forth in claim 7, characterized in that, when the insulating film deposited on the high melting point metallic silicide film is a nitride film, the insulating film which becomes a material of a side spacer formed on the side wall of the polycide gate electrode is an oxide film.

9. A method of manufacturing a semiconductor device as set forth in claim 1, characterized in that the insulating film deposited on the high melting point metallic silicide film is composed of a laminate structure of an oxide film, a nitride film, and another oxide film different from the oxide film.

10. A method of manufacturing a semiconductor device as set forth in claim 9, characterized in that, when the insulating film deposited on the high melting point metallic silicide film has a laminate structure and an uppermost layer thereof is an oxide film, the insulating film which becomes a material of a side spacer formed on the side wall of the polycide gate electrode is a nitride film.

11. A method of manufacturing a semiconductor device as set forth in claim 1, characterized in that doping of the first conductivity type impurity at a concentration of 1×10¹⁹ atoms/cm³ or higher to the portion and the entire region of the first region of the second polycrystalline silicon film is performed simultaneously with doping to a diffusion region of the first conductivity type MOS transistor, and doping of the second conductivity type impurity at a concentration of 1×10¹⁹ atoms/cm³ or higher to the portion and the entire region of the second region of the second polycrystalline silicon film is performed simultaneously with doping to a diffusion region of the second conductivity type MOS transistor.
